(19) United States
(12) Patent Application Publication
(10) Pub. No.: US 2012/0202344 A1
(43) Pub. Date: Aug. 9, 2012

(54) MANUFACTURING METHOD OF SEMICONDUCTOR DEVICE

(75) Inventors: Masaru NOZUE, Tokyo (JP); Hiroshi OSHITA, Kanagawa (JP); Hiroyuki MASUDA, Kanagawa (JP); Hiroki TAKEWAKA, Kanagawa (JP)

(73) Assignee: RENESAS ELECTRONICS CORPORATION

(21) Appl. No.: 13/364,749

(22) Filed: Feb. 2, 2012

(30) Foreign Application Priority Data
Feb. 3, 2011 (JP) 2011-021372

(51) Int. Cl. H01L 21/768

(52) U.S. Cl. 438/643; 257/E21.584

(57) ABSTRACT

To provide a technology capable of preventing corrosion of a Cu wiring and thereby improving a production yield of a semiconductor device, a manufacturing method of a semiconductor device includes the steps of: removing a portion of a Cu film other than that in a wiring trench in a semiconductor substrate by CMP using a polishing slurry, removing a portion of a barrier metal film other than that in the, wiring trench by CMP using a polishing slurry containing an anticorrosive, polishing the surface of the Cu film and the surface of the barrier metal film by CMP using pure water, thereafter cleaning the semiconductor substrate with pure water without applying an anticorrosive thereto or without cleaning it with a chemical liquid, and thereafter cleaning the semiconductor substrate with a chemical liquid without applying an anticorrosive thereto.

### CROSS-REFERENCE TO RELATED APPLICATIONS

The disclosure of Japanese Patent Application No. 2011-21372 filed on Feb. 3, 2011 including the specification, drawings and abstract is incorporated herein by reference in its entirety.

### BACKGROUND

The present invention relates to a manufacturing technology of a semiconductor device, in particular, to a technology effective when applied to the manufacture of metal wirings using a chemical mechanical polishing (CMP) process.

For example, Japanese Patent Laid-Open No. 2009-238896 (Patent Document 1) discloses a technology capable of suppressing corrosion of a buried wiring by employing post-CMP cleaning at a rotation velocity of a wafer set at a low level so as to permit a cleaning liquid to have almost a uniform thickness and thereby making uniform a dissolved oxygen concentration on the device surface of the wafer.

Japanese Patent Laid-Open No. Hei 8(1996)-64594 (Patent Document 2) discloses a technology capable of preventing corrosion of the surface of a wiring by using, upon polishing a metal film to form the wiring, an abrasive liquid containing a BTA component to form an anticorrosive film on the surface of a newly-formed metal film prior to occurrence of corrosion.

Japanese Patent No. 3111979 (Patent Document 3) discloses a technology of carrying out, in a cleaning step after polishing treatment of copper, a first-stage particle removal treatment in an alkaline or hydrogen reduction atmosphere and a second-stage treatment in an acidic atmosphere in combination and thereby preventing contamination of a copper wiring portion due to etching.

Japanese Patent Laid-Open No. 2002-93760 (Patent Document 4) discloses a technology capable of preventing corrosion of copper by applying a solution containing a corrosion preventive to a wafer after polishing copper in a CMP apparatus and keeping at least the wetted state of the polished copper surface.

Japanese Patent Laid-Open No. 2007-43183 (Patent Document 5) discloses a technology capable of preventing corrosion of copper by subjecting, using a first polishing pad on a first polishing platen, a first main surface of a wafer to chemical mechanical polishing treatment for the removal of copper with a polishing slurry and then polishing the first main surface of the wafer while supplying a chemical liquid containing an anticorrosive of copper onto a second polishing pad on a second polishing platen.

### PATENT DOCUMENTS

[Patent Document 1] Japanese Patent Laid-Open No. 2009-238896

[Patent Document 2] Japanese Patent Laid-Open No. Hei 8(1996)-64594

[Patent Document 3] Japanese Patent No. 3111979

[Patent Document 4] Japanese Patent Laid-Open No. 2002-93760

[Patent Document 5] Japanese Patent Laid-Open No. 2007-43183

### SUMMARY

It is desirable to reduce wiring resistance and wiring capacitance in order to suppress wiring delay which will otherwise occur as a result of high integration of semiconductor devices. For the reduction of the wiring resistance, solution in accordance with the design technology and employment of a wiring using a copper (Cu) film as a main conductor (such wiring will hereinafter be called “Cu wiring”) are under investigation. For the formation of a Cu wiring, employed is a so-called damascene process, that is, a method of forming a Cu wiring inside a trench by successively depositing a barrier metal film and a Cu film over a substrate including the inside of the trench formed in an insulating film and then, removing the barrier metal film and the Cu film in a region outside the trench by using a CMP process. For the reduction of the wiring capacitance, on the other hand, employment of a material having a dielectric constant of approximately 2 to 3, which is a relatively low dielectric constant, is under investigation.

The present inventors have studied a manufacturing method of a Cu wiring using the damascene process. The manufacturing method of a Cu wiring, however, has various technical problems which will be described below.

It has been confirmed by the present inventors that in a miniaturized semiconductor device, local corrosion (pitting corrosion), disconnection, or the like appeared on the surface of a Cu wiring formed using a CMP process, particularly, a Cu wiring having a line width of 70 nm or less. Such phenomena did not occur in a Cu wiring having a line width of 75 nm or greater.

The present inventors therefore investigated the cause of corrosion of a Cu wiring having a line width of 70 nm or less. As a result, the present inventors found that an anticorrosive added to a polishing slurry used for polishing of a barrier metal film remains on the surface of a Cu film and, in a cleaning step of a wafer which is conducted subsequently, the anticorrosive remaining on the surface of a Cu film is contacted with a chemical liquid used for cleaning, whereby the Cu wiring is etched locally. The barrier metal film is a conductor film formed below the Cu film and functions as a protecting film to prevent diffusion of the Cu film.

Described specifically, in the cleaning step in the damascene process, after polishing metal films (barrier metal film and Cu film) deposited on a wafer, the wafer is usually subjected to cleaning with a chemical liquid for removing a foreign matter or a Cu oxide to be polished, and finish cleaning to be conducted subsequently. An acidic or weak alkaline chemical liquid is used, in the cleaning with a chemical liquid, while pure water (de-ionized water: DIW) is used in finish cleaning.

As illustrated in FIG. 14, when the upper surface of a Cu film configuring a Cu wiring is recessed relative to the upper surface of an insulating film as a result of polishing, an anticorrosive which has entered in this recessed portion sometimes remains as a residue in a narrow-width Cu wiring having a line width of 70 nm or less. Cleaning with a chemical liquid without removing the anticorrosive on the surface of the Cu wiring inevitably etches an exposed portion of the Cu wiring due to a concentration cell effect (refer to Japanese Patent Laid-Open. No. 2009-238896 (Patent Document 1)). The anticorrosive is added to a polishing slurry in order to suppress corrosion of the surface of a Cu film during polishing of a barrier metal film. The Cu film can be protected with a hydrophobic film made of a complex between the anticorrosive and Cu formed on the surface of the Cu film. Examples of the anticorrosive include benzotriazole (BTA) and adenine-based anticorrosives.

The term “concentration cell” as used herein means a cell, as illustrated in FIG. 15, formed when there are at least two exposed portions of a Cu wiring (surface-exposed portions of the Cu wiring not covered with the anticorrosive) and due to uneven distribution of dissolved oxygen contained in the chemical liquid, the concentration of dissolved oxygen with which one of the portions is immersed is different from the concentration of a dissolved oxygen with which the other one is immersed. The one of the exposed portions is short-circuited with the other portion via the Cu wiring so that Cu ions are eluted from the one of the exposed portions while Cu ions are precipitated at the other portion (cathode).

As a means for preventing etching of a Cu wiring, there is considered a method of completely removing an anticorrosive which has remained on the surface of the Cu wiring, prior to the contact of the surface of the Cu wiring to a chemical liquid by using polishing with water (polishing not with a polishing slurry but with water). Elongation of a polishing time with water for complete removal of an anticorrosive which has remained on the surface of the Cu wiring, however, causes charge-up due to a polishing slurry remaining in the irregularities or grooves on the surface of a polishing pad or friction and generates corrosion of the Cu wiring. In addition, it extends the processing time and reduces productivity.

As another means for preventing corrosion of a Cu wiring, there is considered a method of, after polishing, applying an anticorrosive onto the whole surface of a polished wafer to cover the locally exposed portion of the Cu wiring, as described in Japanese Patent Laid-Open No. 2002-93760 (Patent Document 4). The anticorrosive is, however, gradually removed in scrub cleaning which will be conducted subsequently so that due to inevitable local exposure of the Cu wiring, corrosion of the Cu wiring may occur. In addition, an increase in the using amount of the anticorrosive leads to an increase in the cost necessary for the anticorrosive itself and also for the treatment of a waste liquid.

As described in Japanese Patent No. 3111979, cleaning in an alkaline or hydrogen reduction atmosphere after polishing can prevent corrosion of a Cu wiring. Even by this method, however, there is a risk of corrosion of a Cu wiring occurring due to a concentration cell effect in the case where the Cu wiring has locally exposed portions and the dissolved oxygen concentration or electrolyte ion concentration of a liquid covering the surface of the Cu wiring differs at different positions.

An object of the invention is to provide a technology capable of preventing corrosion of a Cu wiring and improving a production yield of a semiconductor device.

According to one aspect of the invention, a manufacturing step of forming, in a wiring trench formed in an insulating film over a main surface of a semiconductor substrate, a wiring having a Cu film as a main conductor includes a step of removing a Cu film other than that in the wiring trench through CMP using a polishing slurry, a step of removing a barrier metal film other than that in the wiring trench through CMP with a polishing slurry containing an anticorrosive, a step of polishing the respective surfaces of the Cu film and the barrier metal film through CMP using pure water, a step of cleaning a semiconductor substrate with pure water without applying an anticorrosive and without using a chemical liquid, and a step of cleaning the semiconductor substrate with a chemical liquid without applying an anticorrosive, which steps are conducted successively.

By the foregoing technique, corrosion of a Cu wiring can be prevented and a production yield of a semiconductor device can be improved.

The above-described and the other objects and novel features of the invention will be apparent from the description herein and accompanying drawings.

### BRIEF DESCRIPTION OF THE DRAWINGS

FIG. 1 is a fragmentary cross-sectional view, for describing a manufacturing method of a semiconductor device according to one embodiment of the invention;

FIG. 2 is a fragmentary cross-sectional view of the same position as that described in FIG. 1 during a manufacturing step of the semiconductor device following that of FIG. 1;

FIG. 3 is a fragmentary cross-sectional view of the same position as that described in FIG. 1 during a manufacturing step of the semiconductor device following that of FIG. 2;

FIG. 4 is a fragmentary cross-sectional view of the same position as that described in FIG. 1 during a manufacturing step of the semiconductor device following that of FIG. 3;

FIG. 5 is a schematic top view showing a single-wafer type CMP apparatus according to the one embodiment of the invention;

FIG. 6 is a step chart showing one example of the flow of a CMP process according to the one embodiment of the present invention;

FIG. 7 is a schematic perspective view showing a region of a polishing platen of a polishing portion of the single-wafer type CMP apparatus;

FIG. 8 is a schematic perspective view showing a region of a double-side cleaning unit (roll brush cleaning region) of a cleaning portion of the single-wafer type CMP apparatus;

FIG. 9 is a schematic perspective view showing a region of a single-side cleaning unit (pen brush cleaning region) of the cleaning portion of the single-wafer type CMP apparatus;

FIG. 10(a) and FIG. 10(b) are enlarged fragmentary cross-sectional views showing a wiring when cleaning with pure water is not performed and a wiring when cleaning with pure water is performed, each in a CMP step, respectively;

FIG. 11 is a fragmentary cross-sectional view showing the same position as that of FIG. 1 during a manufacturing step of the semiconductor device following that of FIG. 4;

FIG. 12 is a fragmentary cross-sectional view showing the same position as that of FIG. 1 during a manufacturing step of the semiconductor device following that of FIG. 11;

FIG. 13 is a fragmentary cross-sectional view showing the same position as that of FIG. 1 during a manufacturing step of the semiconductor device following that of FIG. 12;

FIG. 14 is a schematic cross-sectional view of a Cu wiring for describing an anti-corrosive which has remained on the surface of a Cu wiring investigated by the present inventors; and

FIG. 15 is a schematic cross-sectional view of a Cu wiring for describing a concentration cell effect which has occurred in the Cu wiring investigated by the present inventors.

### DETAILED DESCRIPTION

In the following embodiments, a description will be made after divided in plural sections or in plural embodiments if necessary for convenience's sake. These plural sections or embodiments are not independent each other, but in a relation such that one is a modification example, details or complementary description of a part or whole of an other unless otherwise specifically indicated.

In the following embodiments, when a reference is made to the number of elements (including the number, value, amount, and range), the number is not limited to a specific number but can be greater than or less than the specific number unless otherwise specifically indicated or principally apparent that the number is limited to the specific number. Moreover, in the following embodiments, constituent elements (including elemental steps) are not always essential unless otherwise specifically indicated or principally apparent that the element is essential. Similarly, in the following embodiments, when a reference is made to the shape or positional relationship of the constituent elements, that substantially analogous or similar to it is also embraced unless otherwise specifically indicated or principally apparent that it is not. This also applies to the above-described value and range.

In the drawings used in the following embodiments, some plan views may be hatched in order to facilitate viewing of them. In the below-described embodiments, MISFET (metal insulator semiconductor field effect transistor) representative of field effect transistors is abbreviated as MIS, p-channel MISFET is abbreviated as pMIS, and n channel MISFET is abbreviated as nMIS. In the below-described embodiments, the term “wafer” mainly means an Si (silicon) single crystal wafer, but it also means an SOI (silicon on insulator) wafer, an insulating film substrate for forming an integrated circuit thereover, or the like. The shape of the wafer is not limited to disc or substantially disc, but it may be square or rectangular.

In all the drawings for describing the below-described embodiments, members having like function will be identified by like reference numerals and overlapping descriptions will be omitted. The embodiments of the present invention will hereinafter be described specifically referring to accompanying drawings.

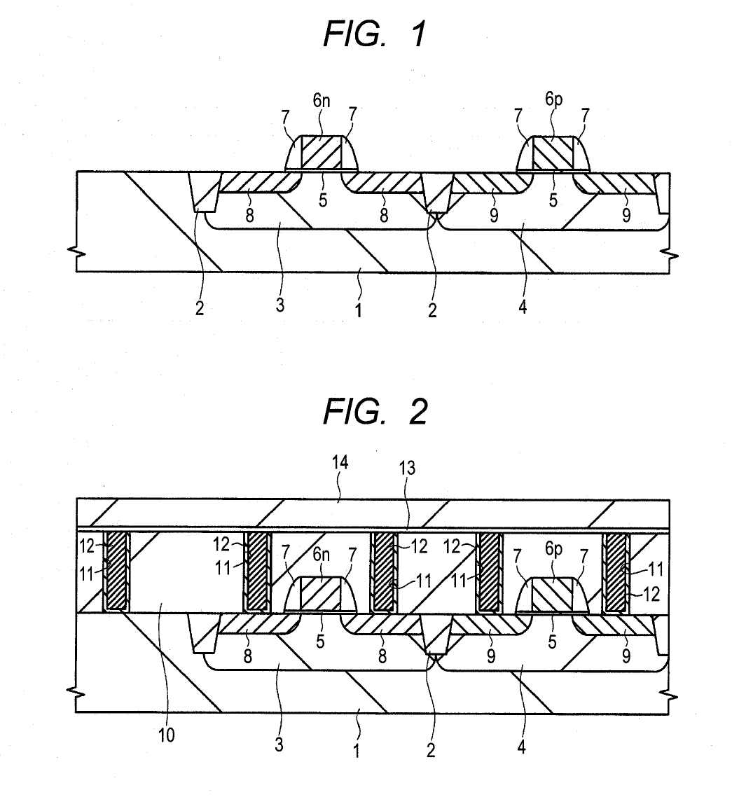

The manufacturing method of a semiconductor device according to an embodiment of the invention will next be described referring to FIGS. 1 to 13. The semiconductor device has various semiconductor elements such as field effect transistor, resistor element, and capacitor. In the present embodiment, a CMIS (complementary metal insulator oxide semiconductor) device is shown as an example.

As illustrated in FIG. 1, a semiconductor substrate (semiconductor thin plate having a substantially disk-shaped plane, so-called “wafer”) made of, for example, single crystal silicon is prepared. Next, an isolation portion 2 made of an insulating film is formed in an element isolation region in the main surface of the semiconductor substrate 1. Then, an impurity exhibiting p type conductivity is ion-implanted into a portion of the semiconductor substrate 1 in a region in which an nMIS is to be formed (nMIS formation region) and a p well 3 is formed. Similarly, an impurity exhibiting n type conductivity is ion-implanted into a portion of the semiconductor substrate 1 in a region in which a pMIS is to be formed (pMIS formation region) and an n well 4 is formed.

Next, a gate insulating film 5 is formed on the main surface of the semiconductor substrate 1 (on the surface of each of the p well 3 and the n well 4). Then, a gate electrode 6n of the nMIS is formed on the gate insulating film 5 in the nMIS formation region and similarly, a gate electrode 6p of the pMIS is formed on the gate insulating film 5 in the pMIS formation region.

Next, a sidewall 7 is formed on the side walls of the gate electrode 6n of the nMIS and the gate electrode 6p of the pMIS. Then, an impurity exhibiting n type conductivity is ion-implanted into the p well 3 on both sides of the gate electrode 6n of the nMIS and n type semiconductor regions 8 functioning as source/drain of the nMIS are formed in self alignment with the gate electrode 6n and the sidewall 7. Similarly, an impurity exhibiting p type conductivity is ion-implanted into the n well 4 on both sides of the gate electrode 6p of the pMIS and p type semiconductor regions 9 functioning as source/drain of the pMIS are formed in self alignment with the gate electrode 6p and the sidewall 7.

Next, as illustrated in FIG. 2, after formation of an insulating film 10 on the main surface of the semiconductor substrate 1, the insulating film 10 is dry etched with a resist pattern as a mask to form coupling holes 11. The coupling holes 11 are formed in necessary portions, for example, on the n type semiconductor regions 8 or on the p type semiconductor regions 9. Then, a plug 12 having, for example, a tungsten (W) film as a main conductor is formed in each coupling hole 11.

Next, a stopper insulating film 13 and an insulating film for forming a wiring are formed successively on the main surface of the semiconductor substrate 1. The stopper insulating film 13 is a film serving as an etching stopper when a trench is formed in the insulating film 14 and a material having an etch selectivity relative to the insulating film 14 is employed. For example, a silicon nitride film formed by plasma CVD (chemical vapor deposition) can be used as the stopper insulating film 13, while for example, a silicon oxide film formed by plasma CVD can be used as the insulating film 14. In the stopper insulating film 13 and the insulating film 14, a first-level wiring M1 which will be described next is formed.

Next, the first-level wiring M1 is formed by the single damascene process.

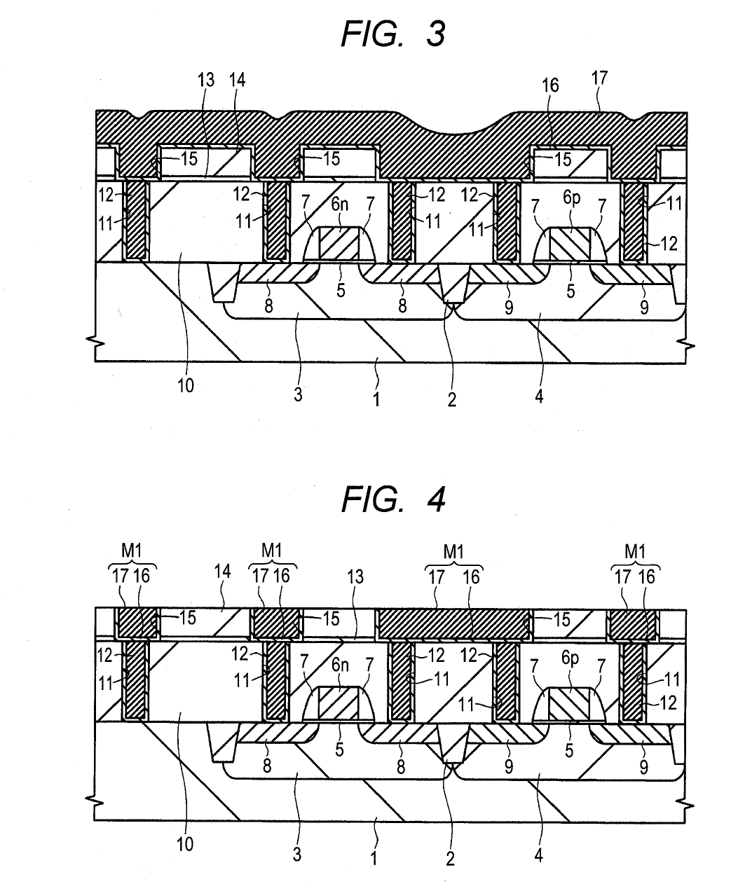

First, as illustrated in FIG. 3, wiring trenches 15 in a recessed form are formed in predetermined regions of the stopper insulating film 13 and the insulating film 14 by using dry etching with a resist pattern as a mask. The minimum trench width of the wiring trench 15 is, for example, 70 nm or less. Then, a barrier metal film 16 is formed on the main surface of the semiconductor substrate 1. The barrier metal film 16 is, for example, a titanium nitride (TiN) film, tantalum (Ta) film, or a tantalum nitride (TaN) film. Then, a Cu seed layer (not illustrated) is formed on the barrier metal film 16 by using CVD or sputtering, followed by the formation of a Cu-plated film 17 on the seed layer by using electroplating. The Cu-plated film 17 is filled in the wiring trench 15.

Then, the Cu-plated film 17, the seed layer, and the barrier metal film 16 in a region other than the inside of the wiring trench 16 are removed using a CMP process to form the first-level wiring M1 having a Cu film as a main conductor as illustrated in FIG. 4. In the present embodiment, the Cu film serving as a main conductor configuring the first-level wiring M1 is formed using electroplating, but it may be formed using CVD, sputtering, sputtering reflow, or the like process.

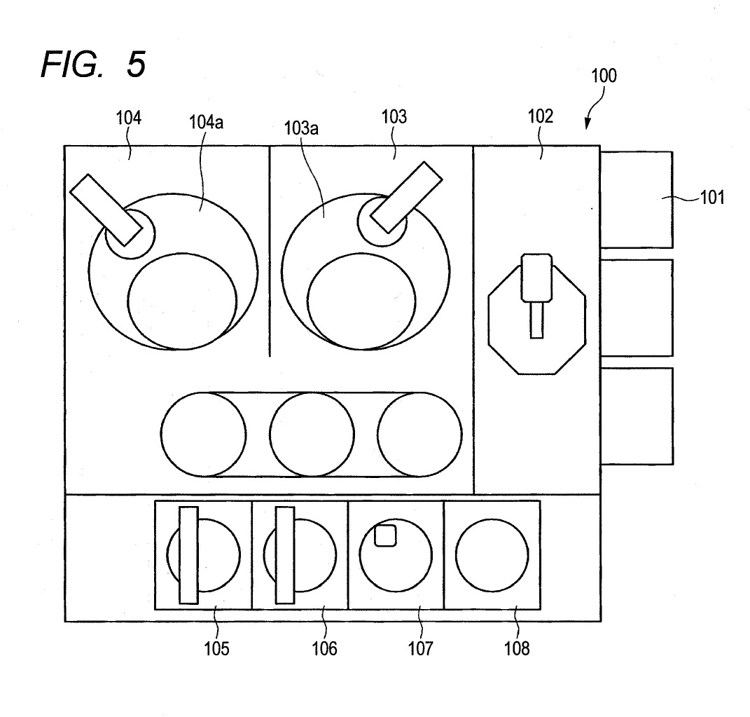

A formation method of the first-level wiring M1 by using a CMP process will next be described in detail referring to FIGS. 5 to 10.

In the CMP process in the present embodiment, a single-wafer CMP apparatus equipped with a polishing portion and a cleaning portion as illustrated in FIG. 5 is used. This CMP apparatus 100 is comprised mainly of a load port in which a wafer storage container (FOUP: front opening unified port) 101 holding therein wafers to be processed is set, a transfer portion 102 having a wafer transfer robot for loading/unloading the wafers, a first polishing portion 103 for polishing Cu films (Cu-plated film 17 and seed layer), a second polishing portion 104 for polishing a barrier metal film (barrier metal film 16), a first cleaning portion 105 comprised of a first double-side cleaning unit having a roll brush (roll sponge), a second cleaning portion 106 comprised of a second double-side cleaning unit having a roll brush (roll sponge), a third cleaning portion 107 comprised of a single-side cleaning unit having a pen brush (pen sponge), and a drying portion 108 comprised of a drying unit for drying the processed wafer.

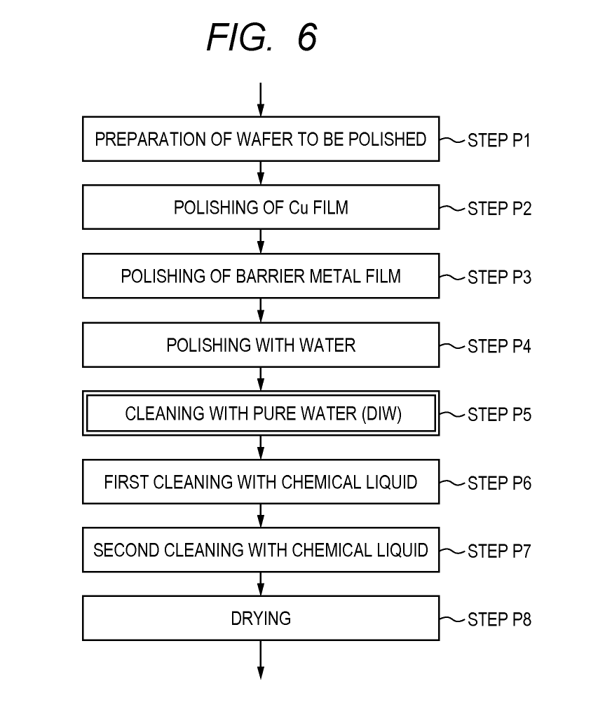

Next, the flow of wafer processing in the CMP step in the present embodiment will next be described briefly referring to FIGS. 5 and 6.

The wafer storage container 101 holding therein wafers to be processed is set in the load port (Step P1 of FIG. 6).

Next, the wafer is transferred to the first polishing portion 103 by using the wafer transfer robot which the transfer portion 102 has and is set on a platen (polishing machine) 103a, at which an unnecessary portion of the Cu film is removed by CMP using a polishing slurry (Step P2 of FIG. 6).

Then, the wafer is transferred to the second polishing portion 104 from the first polishing portion 103 and is set on a platen (polishing machine) 104a at which an unnecessary portion of the barrier metal film is removed by CMP using, a polishing slurry containing an anticorrosive (Step P3 of FIG. 6). The anticorrosive contained in the polishing slurry remains on the wafer so that it is removed by polishing with pure water (Step P4 of FIG. 6). This polishing with water, however, cannot completely remove the anticorrosive which has remained on the surface of the Cu film, and the anticorrosive still remains on the surface of a portion of the Cu film (Cu film buried in the wiring trench 15 having a trench depth of 70 nm or less).

Then, the wafer is transferred from the second polishing portion 104 to the first cleaning portion 105 and it is cleaned with pure water (DIW) in the first double-side cleaning unit (Step P5 of FIG. 6). Between the step P4 and the step P5, both cleaning with a chemical liquid and anticorrosive treatment (application of an anticorrosive (for example, BTA)) are not performed. The anticorrosive which has remained on the surface of the Cu film is completely removed by this cleaning with pure water.

Then, the wafer is transferred from the first cleaning portion 105 to the second cleaning portion 106 and in the second double-side cleaning unit, it is cleaned with a chemical liquid. Then, the wafer is rinse-cleaned with pure water (step P6 of FIG. 6). Between the step P5 and the step P6, anticorrosive treatment (application of an anticorrosive (for example, BTA) is not performed.

The wafer is then transferred from the second cleaning portion 106 to the third cleaning portion 107 and in the single-side cleaning unit, it is cleaned with a chemical liquid. The wafer is then rinse-cleaned with pure water (step P7 of FIG. 6).

Next, the wafer is transferred from the third cleaning portion 107 to the drying portion 108 and it is dried in the drying unit (Step P8 of FIG. 6).

The wafer is then returned from the drying portion 108 to the wafer storage container 101 by using the wafer transfer robot.

Specific methods for processing a wafer (Steps P2 to P8 of FIG. 6) will next be described.

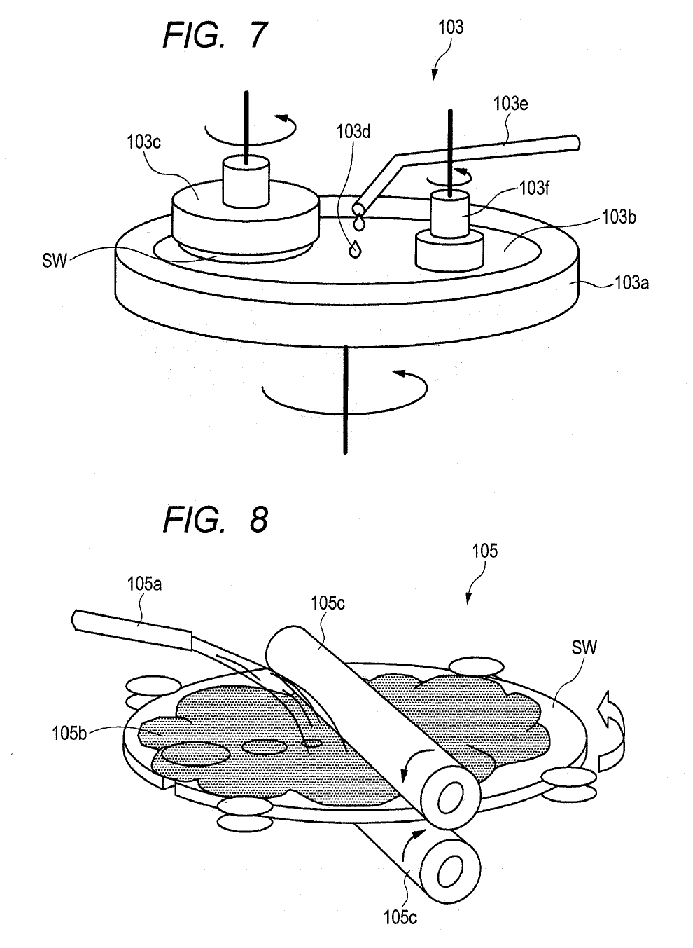

(1) Polishing of Cu film (Step P2 of FIG. 6): An unnecessary portion of the Cu films (Cu plated film 17 and seed layer) is removed in the first polishing portion 103 illustrated in FIG. 7. The first polishing portion 103 has a chassis having an open top and it has, at the upper end portion of a rotation shaft attached to the chassis, a platen 103a to be rotated and driven by a motor. The platen 103a has, on the surface thereof, a porous polishing pad 103b obtained by uniformly attaching a synthetic resin (for example, expanded polyurethane resin).

This first polishing portion 103 is equipped with a wafer retention mechanism (wafer carrier) 103c for retaining therewith a wafer SW. A drive shaft to which the wafer retention mechanism 103c has been fixed is, together with the wafer retention mechanism 103c, rotated and driven by a motor and at the same time, is moved up and down above the platen 103a.

The wafer SW is retained in the wafer retention mechanism 103c, with its, main surface, that is, the surface to be polished, facing downward by a vacuum adsorption mechanism provided in the wafer retention mechanism 103c. At the lower end portion of the wafer retention mechanism 103c, a recess for housing the wafer SW is formed. When the wafer SW is housed in this recess, the surface of the wafer SW to be polished is almost flush with or slightly protrudes from the lower end surface of the wafer retention mechanism 103c.

Slurry supply equipment 103e for supplying a polishing slurry 103d between the surface of the polishing pad 103b and the surface of the wafer SW to be polished is provided above the platen 103a, and the surface of the wafer SW to be polished is polished chemically and mechanically by the polishing slurry 103d supplied from its lower end. As the polishing slurry 103d, that having abrasive particles, such as silicon oxide (SiO₂), as a main component and obtained by dispersing them in water is used.

The first polishing portion 103 is equipped with a dresser 103f which is a tool for dressing the surface of the polishing pad 103b. This dresser 103f is attached to the lower end portion of the drive shaft which moves up and down above the platen 103a and is rotated and driven by a motor.

In the above-described first polishing portion 103, the wafer SW is retained by the wafer retention mechanism 103c and the surface thereof to be polished is polished until an unnecessary portion of the Cu film is removed completely. Polishing is performed, for example, under the following conditions: pressure to be applied to the back surface of wafer SW: 2 psi, the number of rotations of wafer SW: 80 rpm, the number of rotations of platen 103a: 80 rpm, and discharge rate of polishing slurry 103d: 300 ml/min.

(2) Polishing of barrier metal film (step P3 of FIG. 6): In the second polishing portion 104 having a substantially similar structure to that of the above-described first polishing portion 103 illustrated in FIG. 7, an unnecessary portion of the barrier metal film (barrier metal film 16) is removed.

In the second polishing portion 104, the wafer SW is retained by the wafer retention mechanism and the surface thereof to be polished is polished until an unnecessary portion of the barrier metal film is removed completely. Polishing is performed, for example, under the following conditions: pressure to be applied to the back surface of wafer SW: 2 psi, the number of rotations of wafer SW: 70 rpm, the number of rotations of platen: 70 rpm, and discharge rate of polishing slurry: 300 ml/min. The polishing slurry used for the removal of the barrier metal film contains an anticorrosive for protecting the surface of the Cu film, for example, BTA or adenine-based anticorrosive.

(3) Polishing with water (Step p4 of FIG. 6): After completion of the polishing of the barrier metal film with the polishing slurry in the preceding step P3 (polishing of the barrier metal film), the surface of the wafer SW to be polished (the surface of the Cu film and the surface of the barrier metal film) is polished with pure water instead of the polishing slurry, while bringing the surface of the wafer to be polished into contact with the platen of the second polishing portion 104. The anticorrosive which has remained on the surface of the Cu film is thus removed. Polishing with water is performed, for example, under the following conditions: pressure to be applied to the back surface of wafer SW: 1 psi and discharge rate of pure water: 1000 ml/min. The polishing with water is preferably performed for from 5 to 15 seconds. It can differ, however, depending upon the nature of the polishing slurry used in the preceding step P3 (polishing of the barrier metal film) or the anticorrosive contained therein. As the polishing time becomes smaller, the anticorrosive and foreign matter are not removed completely. On the contrary, as the polishing time becomes longer, charge up of the polished surface of the wafer SW occurs, leading to corrosion of the Cu film, because the surface of the Cu film having the anticorrosive unevenly thereon is polished with water. It is therefore difficult to completely remove the anticorrosive and the anticorrosive partially remains on the surface of the Cu film (Cu film buried in the wiring trench 15 having a trench width of 70 nm or less).

(4) Cleaning with pure water (DIW) (Step P5 of FIG. 6): the first double-side cleaning unit of the first cleaning portion 105 illustrated in FIG. 8, the wafer SW is washed with pure water and the anticorrosive which has remained on the surface of the wafer SW to be polished (surface of the Cu film) is removed completely. In the first double-side cleaning unit, pure water 105b is supplied from pure water supply equipment 105a and for example, a pair of cylindrical sponge-like roll brushes 105c is rotated at high speed while being brought into contact with the two main surfaces of the wafer SW, respectively, so as to move across the wafer SW. Cleaning with pure water is performed, for example, under the following conditions: the number of rotations of roll brush 105c: 200 rpm, the number of rotations of wafer SW: 10 rpm, and cleaning time: from 30 to 60 seconds.

Then, the roll brushes 105c are relaxed to separate them from the two main surfaces of the wafer Sw. The anticorrosive which has remained on the surface of the Cu film is removed completely by this cleaning with pure water.

Instead of the roll brush 105c, a roll brush and a pen brush may be used in combination. The roll brush and the pen brush both can remove foreign matters attached to the surface of the wafer by making use of a physical force. In particular, the pen brush can push foreign matters from the center of the wafer to the outer circumference thereof so that it can prevent re-deposition of the foreign matters to the wafer SW and therefore has a finish effect of cleaning. When the roll brush and pen brush are used in combination, it is therefore preferred to use the roll brush and then use the pen brush. Whether only the roll brush 105c is used or the roll brush and the pen brush are used in combination is determined, depending on the amount of an anticorrosive which has remained on the polished surface of the wafer SW after completion of the polishing of the Cu film and the barrier metal film, or depending on the degree of the adsorption property of it.

(5) First cleaning with chemical liquid (Step P6 of FIG. 6): In the second double-side cleaning unit of the second cleaning portion 106 having a substantially similar structure to that of the first double-side cleaning unit of the first cleaning portion 105 illustrated in FIG. 8, first cleaning of the wafer SW with a chemical liquid is performed to remove foreign matters attached to the wafer SW. Described specifically, in the second double-side cleaning unit, a chemical liquid is supplied from chemical liquid supply equipment and for example, a pair of cylindrical sponge-like roll brushes is rotated at high speed while being brought into contact with the two main surfaces of the wafer SW, respectively, so as to move across the wafer SW. The first cleaning with a chemical liquid is performed, for example, under the following conditions: the number of rotations of roll brush: 200 rpm, the number of rotations of wafer SW: 10 rpm, and cleaning time: 60 seconds.

The chemical liquid employed in the first cleaning is a solution (acidic chemical solution or weak alkaline chemical solution) other than an electrolyte (solution having a pH of approximately 7). As the acidic chemical solution, an organic acid such as citric acid or oxalic acid is used, while as the weak alkaline chemical solution, an organic alkali is used.

Then, the roll brushes are relaxed to separate them from the two main surfaces of the wafer SW and the wafer is rinse-washed, for example, for 30 seconds while substituting pure water for the chemical liquid.

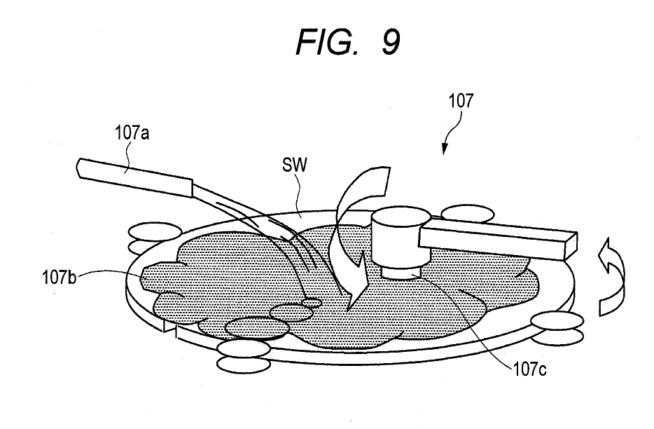

(6) Second cleaning with chemical liquid (Step P7 of FIG. 6). In the single-side cleaning unit of the third cleaning portion 107 illustrated in FIG. 9, the second cleaning of the wafer SW with a chemical liquid is performed to remove foreign matters attached to the wafer SW. In the single-side cleaning unit, a chemical liquid 107b is supplied from chemical-liquid supply equipment 107a and for example, a cylindrical sponge-like pen brush 107c is rotated at high speed while the bottom thereof being brought into contact with the front main surface of the wafer SW. As described above, the pen brush 107c can prevent re-deposition of foreign matters to the wafer SW so that it is suited for use in finish cleaning. The second cleaning with a chemical liquid is performed, for example, under the following conditions: the number of rotations of pen brush 107c: 100 rpm, pressing pressure: 1N, the number of rotations of wafer SW: 300 rpm, and cleaning time: 30 seconds. As the chemical liquid, an organic acid such as citric acid or oxalic acid is used.

Then, the pen brush 107 is raised to separate it from the polished surface of the wafer SW and rinse cleaning, for example, for 50 seconds is performed while substituting pure water for the chemical liquid and decreasing the number of rotations of the wafer to, for example, 10 rpm.

(7) Drying (Step P8 of FIG. 6): In the drying unit of the drying portion 108, the wafer SW is dried. Drying is performed, for example, under the following conditions: the number of rotations of wafer SW: 300 rpm and supply amount of isopropyl alcohol (IPA): 4 L/min.

Thus, in the present embodiment, after polishing of the Cu film (Step P2 of FIG. 6), polishing of the barrier metal film (Step P3 of FIG. 6), and polishing with water (Step P4 of FIG. 6), cleaning with pure water (Step P5 of FIG. 6) is performed. Then, the first cleaning with chemical liquid (Step P6 of FIG. 6) and second cleaning with a chemical liquid (Step P7 of FIG. 7) are performed. This means that prior to the cleaning with a chemical liquid (Step P6 and Step P7 of FIG. 6), cleaning with pure water (Step P5 of FIG. 6) is performed.

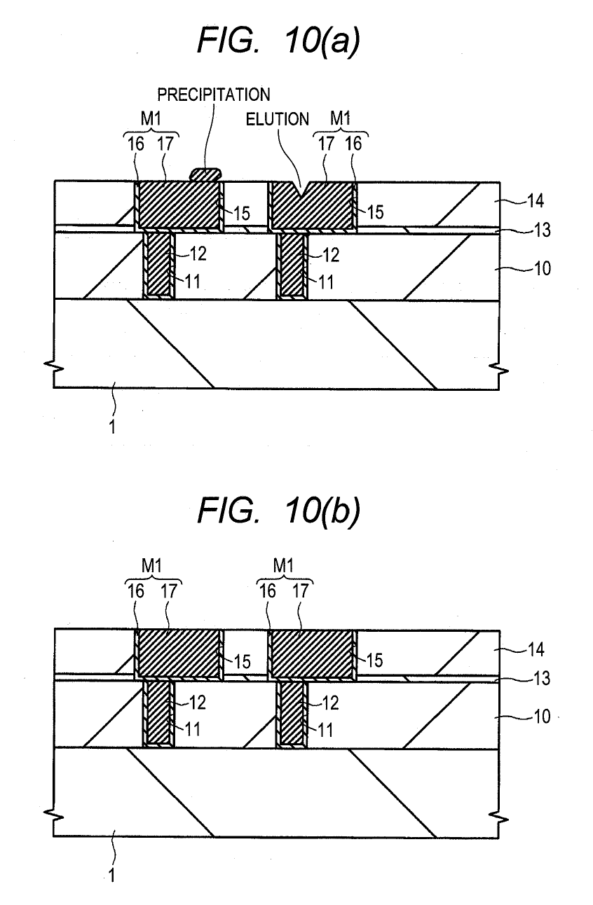

FIG. 10(a) is a schematic cross-sectional view of a first-level wiring M1 formed by the CMP process free of cleaning with pure water (Step P5). In this case, after polishing with water (Step P4), first cleaning with a chemical liquid (Step P6) is performed in the state that the anticorrosive is left on the surface of the Cu film. Local Cu elution and precipitation therefore occur from the wiring M1 due to a concentration cell effect.

FIG. 10(b) is a schematic cross-sectional view of the first-level wiring M1 formed by the CMP process of the present embodiment. In this case, the anticorrosive which has remained on the surface of the Cu film after the polishing with water (Step P4) can be removed completely in the cleaning with pure water (Step P5). Even when the first cleaning with a chemical liquid is then performed, it is therefore possible to prevent local Cu elution and precipitation from the wiring M1 which will otherwise occur due to a concentration cell effect. As a result, corrosion of the wiring M1 can be prevented.

A second-level wiring is then formed by the dual damascene process.

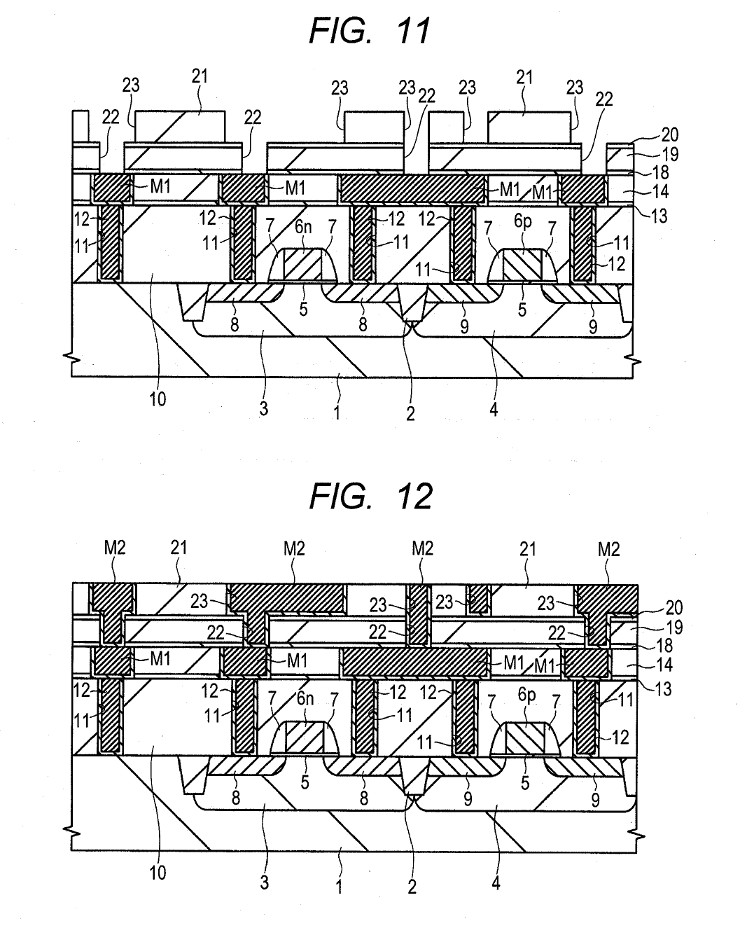

First, as illustrated in FIG. 11, a cap insulating film 18, an interlayer insulating film 19, and a stopper insulating film 20 for wiring formation are formed successively on the main surface of the semiconductor substrate 1. In the cap insulating film 18 and the interlayer insulating film 19, a coupling hole is formed as will be described later. The cap insulating film 18 is made of a material having an etch selectivity relative to the interlayer insulating film 19 and it may be a silicon nitride film formed, for example, by plasma CVD. Further, the cap insulating film 18 has a function as a protective film for preventing diffusion of Cu, which configures the first-level wiring M1. The interlayer insulating film 19 may be an SiOC film which is a Low-k film obtained, for example, by plasma CVD. The stopper insulating film 20 is made of an insulation material having an etch selectivity relative to the interlayer insulating film 19 and an insulating film for wiring formation to be deposited later over the stopper insulating film 20 and it may be, for example, a silicon nitride film formed through plasma CVD.

Next, after dry etching of the stopper insulating film 20 with a hole-formation resist pattern as a mask, an insulating film 21 for wiring formation is formed on the stopper insulating film 20. The insulating film 21 may be, for example, an SiOC film.

Next, the insulating film 21 is dry etched with a resist pattern for wiring trench formation as a mask. Upon this processing, the stopper insulating film 20 serves as an etching stopper. Then, the interlayer insulating film 19 is dry etched with the stopper insulating film 20 and the resist pattern for wiring trench formation as a mask. Upon this dry etching, the cap insulating film 18 serves as an etching stopper. Then, the exposed cap insulating film 18 is removed by dry etching, whereby coupling holes 22 are formed in the cap insulating film 18 and the interlayer insulating film 19 and wiring trenches 23 are formed in the stopper insulating film 20 and the insulating film 21.

Next, as illustrated in FIG. 12, the second-level wiring M2 is formed in the coupling holes 22 and the wiring trenches 23. The second-level wiring M2 is made of a barrier metal layer and a Cu film which is a main conductor and a member for coupling this wiring M2 to the first-level wiring M1 which is a lower-level wiring is formed integral with the second-level wiring M2. First, a barrier metal film is formed on the main surface of the semiconductor substrate 1 including the inside of the coupling holes 22 and the wiring trenches 23. The barrier metal film is, for example, a titanium nitride (TiN) film, a tantalum (Ta) film, or a tantalum nitride (TaN) film. Then, a Cu seed layer is formed on the barrier metal film by using CVD or sputtering, followed by formation of a Cu-plated film on the seed layer by using electroplating. The coupling holes 22 and the wiring trenches 23 are filled with the Cu plated film. The Cu-plated film, the seed layer, and the barrier metal film in a region other than the coupling holes 22 and the wiring trenches 23 are removed using a CMP process to form the second-level wiring M2.

Upon formation of the second-level wiring M2, a CMP process similar to that employed for the formation of the first-level wiring Ml as described referring to FIGS. 5 to 10 is used. This makes it possible to prevent, in the wiring M2 having a line width of 70 nm or less, as in the wiring M1, local elution and precipitation of Cu from the wiring M2 which will otherwise occur due to a concentration cell effect (concentration cell effect which occurs as a result of local exposure of the Cu film configuring the wiring M2 due to remaining of an anticorrosive) in the CMP step.

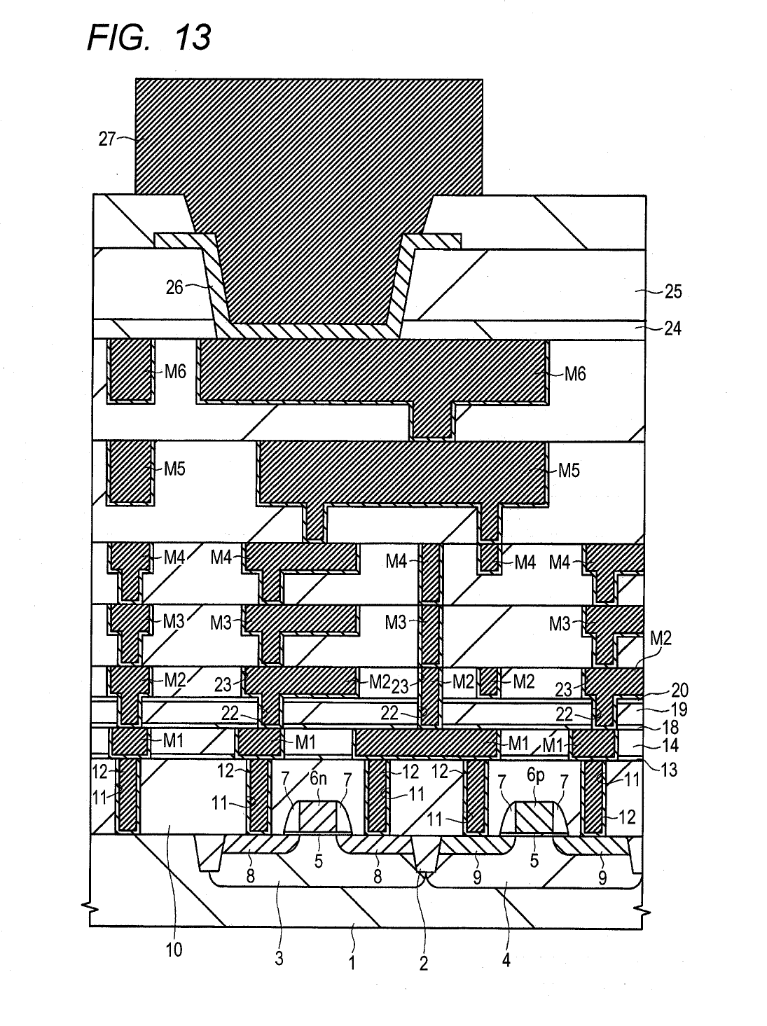

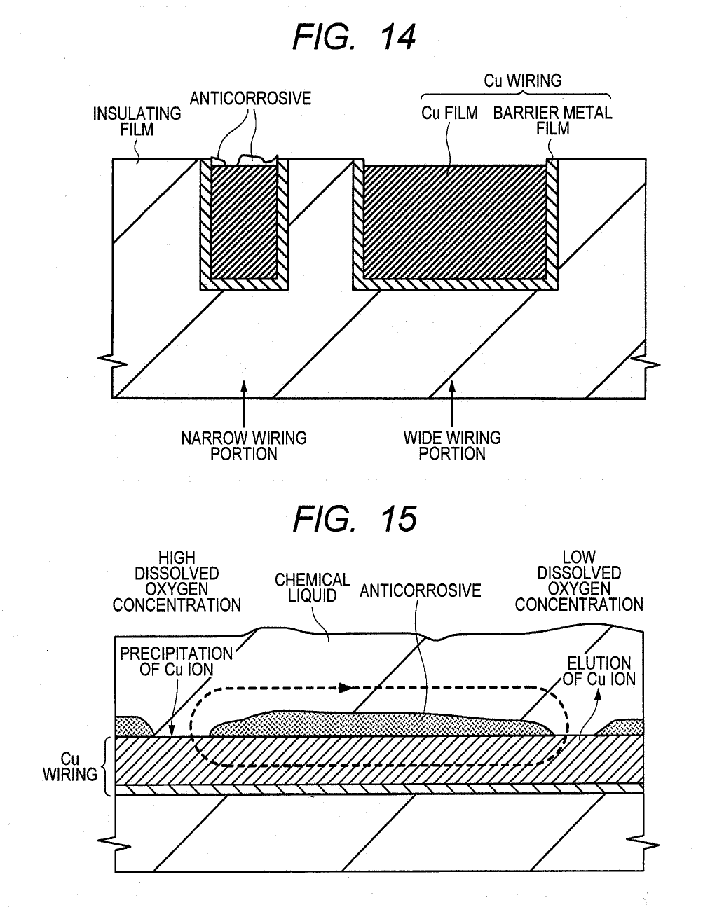

Then, as illustrated in FIG. 13, upper-level wirings are formed, for example, in a similar manner to that employed for the formation of the second-level wiring M2. FIG. 13 shows a semiconductor device having third-level to six-level wirings M3, M4, M5, and M6.

In the present embodiment, a Cu wiring having the minimum line width of 70 nm or less is used as each of the third-level wiring M3 and the fourth-level wiring M4, and a Cu wiring having the minimum line width of 100 nm or more is used as each of the fifth-level wiring M5 and the six level wiring M6. The present invention is therefore applied to the third-level wiring M3 and the fourth-level wiring M4 in which corrosion is likely to occur due to the remaining of the anticorrosive contained in the polishing slurry in the CMP step. On the other hand, the present invention is not always applied to the fifth-level wiring M5 and the sixth-level wiring M6 because corrosion of them due to the remaining of the anticorrosive contained in the polishing slurry in the CMP step is not likely to occur.

Next, a silicon nitride film 24 is formed on the sixth-level wiring M6 and then a silicon oxide film 25 is formed on the silicon nitride film 24. The silicon nitride film 24 and the silicon oxide film 25 function as a passivation film for preventing intrusion of moisture or impurities from the outside or suppressing transmission of α rays.

Next, with a resist pattern as a mask, the silicon nitride film 24 and the silicon oxide film 25 are etched to expose a portion of the sixth-level wiring. M6 (bonding pad portion). A bump underlying electrode 26 made of a film stack of a gold (Au) film, a nickel (Ni) film, and the like is formed on the exposed sixth-level wiring M6, followed by the formation of a bump electrode 27 made of gold (Au), solder or the like on the bump underlying electrode 26. As a result, the semiconductor device according to the present embodiment is substantially completed. This bump electrode 27 serves as an electrode for external coupling. The wafer is then diced into individual chips and the chips are mounted on a package substrate or the like in a known manner. Description on such steps is therefore omitted herein.

Thus, according to the present embodiment, an anticorrosive contained in a polishing slurry can be removed completely in a CMP step, which is one of the manufacturing steps of a Cu wiring so that local elution and precipitation of Cu, which would otherwise occur in a Cu wiring, particularly, a Cu wiring having a line width of 70 nm or less, due to a concentration cell effect, can be prevented. This makes it possible to prevent corrosion of the Cu wiring and improve the production yield of a semiconductor device.

It will be understood by those skilled in the art that the invention is not limited to the above-described embodiment and that various changes can be made without departing from the principles described herein.

What is claimed is:

1. A manufacturing method of a semiconductor device, comprising the steps of:
(a) forming a wiring trench in an insulating film over a main surface of a semiconductor substrate;
(b) forming a barrier metal film over the main surface of the semiconductor substrate so as not to fill the wiring trench therewith, and forming a copper film over the barrier metal film so as to fill the wiring trench therewith;
(c) polishing the copper film by CMP using a first polishing slurry to remove a portion of the copper film outside the wiring trench;
(d) after the step (c), polishing the barrier metal film by CMP using a second polishing slurry containing an anticorrosive to remove a portion of the barrier metal film outside the wiring trench;
(e) after the step (d), polishing the surface of the copper film and the surface of the barrier metal film by CMP using pure water;
(f) after the step (e), cleaning the semiconductor substrate while supplying pure water thereto; and
(g) after the step (f), cleaning the semiconductor substrate while supplying thereto a chemical liquid,
wherein between the step (e) and the step (f), neither application of an anticorrosive onto the main surface of the semiconductor substrate nor cleaning of the semiconductor substrate with a chemical liquid is performed, and
wherein between the step (f) and the step (g), application of an anticorrosive onto the main surface of the semiconductor substrate is not performed.

2. The manufacturing method of a semiconductor device according to claim 1,
wherein the polishing in the step (e) is performed for from 5 to 15 seconds.

3. The manufacturing method of a semiconductor device according to claim 1,
wherein the cleaning in the step (f) is performed for from 30 to 60 seconds.

4. The manufacturing method of a semiconductor device according to claim 1,
wherein in the step (g), a solution other than an electrolyte is used as the chemical liquid.

5. The manufacturing method of a semiconductor device according to claim 1,
wherein in the step (f), the semiconductor substrate is cleaned with a roll brush.

6. The manufacturing method of a semiconductor device according to claim 1,
wherein the step (f) comprises the steps of:
(f1) cleaning the semiconductor substrate with a roll brush while supplying pure water; and
(f2) after the step (f1), cleaning the semiconductor substrate with a pen brush while supplying pure water.

7. The manufacturing method of a semiconductor device according to claim 1,
wherein the step (g) comprises the steps of:
(g1) cleaning the semiconductor substrate with a roll brush while supplying a first chemical liquid; and
(g2) after the step (g1), cleaning the semiconductor substrate with a pen brush while supplying a second chemical liquid.

8. The manufacturing method of a semiconductor device according to claim 1, wherein the wiring trench has a minimum trench width of 70 nm or less.
